(19) United States
(12) Patent Application Publication
(10) Pub. No.: US 2026/0004846 A1
(43) Pub. Date: Jan. 1, 2026

(54) APPARATUS AND METHODS FOR REFERENCE READ TECHNIQUES FOR THRESHOLD SELECTOR DEVICE MEMORY

(71) Applicant: Sandisk Technologies, Inc., Milpitas, CA (US)

(72) Inventors: Christopher J. Petti, Mountain View, CA (US); Raj Ramanujan, Federal Way, WA (US); Dimitri Houssameddine, Sunnyvale, CA (US); Mark Lin, Santa Clara, CA (US)

(73) Assignee: Sandisk Technologies, Inc., Milpitas, CA (US)

(21) Appl. No.: 18/757,932

(22) Filed: Jun. 28, 2024

(51) Int. Cl. G11C 13/00

(52) U.S. Cl. CPC G11C 13/004; G11C 13/0028; G11C 13/003; G11C 13/0069; G11C 2013/0052; G11C 2213/30; G11C 2213/76

(57) ABSTRACT

An apparatus includes memory array having a first memory cell including a first two-terminal element having first and second threshold voltages, a second memory cell including a second two-terminal element having third and fourth threshold voltages, and a control circuit coupled to the memory array. The control circuit is configured to cause the first two-terminal element to have the first threshold voltage, and cause the second two-terminal element to have either the third threshold voltage or the fourth threshold voltage, apply a third voltage signal that increases at a first ramp rate to the first memory cell and the second memory cell, determine that the first memory cell switches from a non-conducting state to a conducting state, and read the second memory cell using the third voltage signal a first predetermined delay time after the first memory cell switches from the non-conducting state to the conducting state.

### BACKGROUND

Memory is widely used in various electronic devices such as cellular telephones, digital cameras, personal digital assistants, medical electronics, mobile computing devices, non-mobile computing devices and data servers. Memory may be non-volatile memory or volatile memory. A non-volatile memory allows information to be stored and retained even when the non-volatile memory is not connected to a source of power (e.g., a battery).

One example of a non-volatile memory is a memory cell that includes a resistance-switching memory element (e.g., a magnetic tunnel junction) coupled in series with a threshold selector device (e.g., an ovonic threshold switch that includes a chalcogenide material or other similar threshold selector device).

An alternative non-volatile memory technology dispenses with the resistance-switching memory element, and uses memory cells that include a threshold selector device as both a memory element and a selector device. For example, a threshold selector device may be programmed to two different resistances (e.g., a high resistance state and a low resistance state) to store information.

An emerging memory technology also uses memory cells that include a threshold selector device as both a memory element and a selector device, but stores memory states using threshold voltage differences instead of resistance differences of the threshold selector device.

For example, a memory cell that includes a threshold selector device such as an ovonic threshold switch or other similar threshold selector device may be programmed to two different threshold voltages (e.g., a high threshold voltage and a low threshold voltage) to store information.

For simplicity, the remaining discussion will use the term “Threshold Selector Memory Cell” to describe a memory cell that includes a threshold selector device as both a memory element and a selector device, and stores data using threshold voltage differences of the threshold selector device.

Although memory systems that include Threshold Selector Memory Cells is promising, numerous design and process challenges remain.

### BRIEF DESCRIPTION OF THE DRAWINGS

FIGS. 1A-1H depict various embodiments of a memory system.

FIG. 2A depicts an embodiment of a portion of a three-dimensional memory array.

FIG. 2B depicts an embodiment of a memory cell of the three-dimensional memory array of FIG. 2A.

FIG. 2C depicts an example current-voltage characteristic of a threshold selector device of FIG. 2B.

FIGS. 3A-3B depict an embodiment of a cross-point memory array.

FIG. 4A is a simplified diagram of a threshold voltage of a threshold selector device versus time, and read and write voltages applied across a Threshold Selector Memory Cell.

FIG. 4B depicts a Threshold Selector Memory Cell voltage versus time for a demarcation read technique.

FIG. 4C is a diagram depicting an example SET and RESET threshold voltage distributions and a read voltage distribution for a population of Threshold Selector Memory Cells.

FIG. 4D depicts an original SET threshold voltage distribution, a drifted SET threshold voltage distribution, and a RESET threshold voltage distribution with no drift of Threshold Selector Memory Cells.

FIG. 5A is a flow diagram of an embodiment of a threshold voltage reference read technique in accordance with this technology.

FIG. 5B is a diagram depicting an example Reference Memory Cell SET threshold voltage distribution, an example Data Memory Cell SET threshold voltage distribution and an example Data Memory Cell RESET threshold voltage distribution.

FIG. 5C depicts the example threshold voltage distributions of FIG. 5B, with two different ramping read voltages.

FIG. 6A is a simplified diagram of an embodiment of an threshold voltage reference read system.

FIG. 6B is a diagram depicting example signals in the example threshold voltage reference read system of FIG. 6A.

FIG. 6C is a simplified diagram of an alternative embodiment of an threshold voltage reference read system.

FIGS. 6D1-6D2 are simplified diagrams of threshold voltage and read voltage distributions for a Fast Read process and a Slow Read Process, respectively, of the example threshold voltage reference read system of FIG. 6C.

FIG. 7 is a flow diagram of an embodiment of a threshold voltage reference read technique in accordance with this technology.

### DETAILED DESCRIPTION

A fundamental material property of threshold selector devices such as ovonic threshold switches is that the threshold voltages of such devices drift with time after being written. As a result, the memory read window of Threshold Selector Memory Cells is limited by this drift characteristic. As a result, highly reliable and low latency memory devices using Threshold Selector Memory Cells is very challenging.

Technology is described for reading Threshold Selector Memory Cells by using a reference memory cell for tracking and mitigating threshold voltage drift in corresponding data memory cells. In embodiments, the reference memory cell and corresponding data memory cells each include a threshold selector device having a first threshold voltage second threshold voltage.

In embodiments, a predetermined value is written to the reference memory cell, each time data are written to the corresponding data memory cells. After the write operation, the threshold voltages of the reference memory cell and corresponding data memory cells the drift with time. In embodiments, the drifted threshold voltage of the reference memory cell is detected and used to cancel out drift components of the corresponding data memory cells.

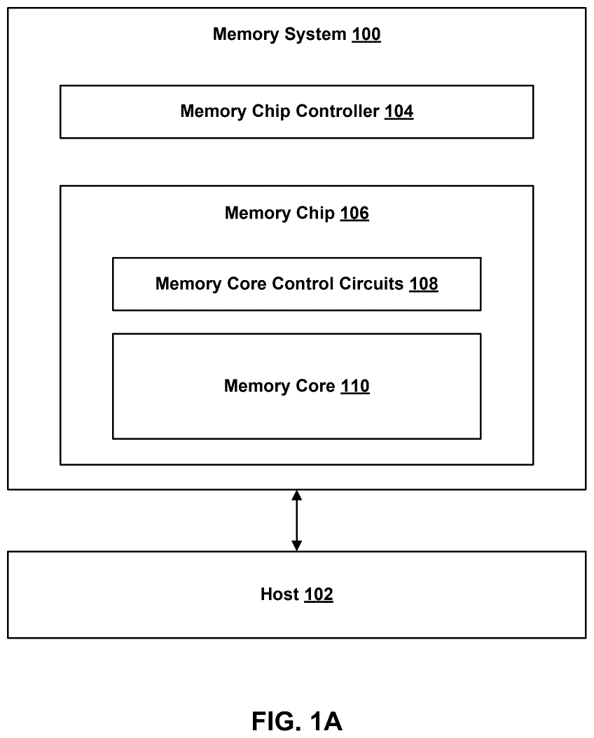

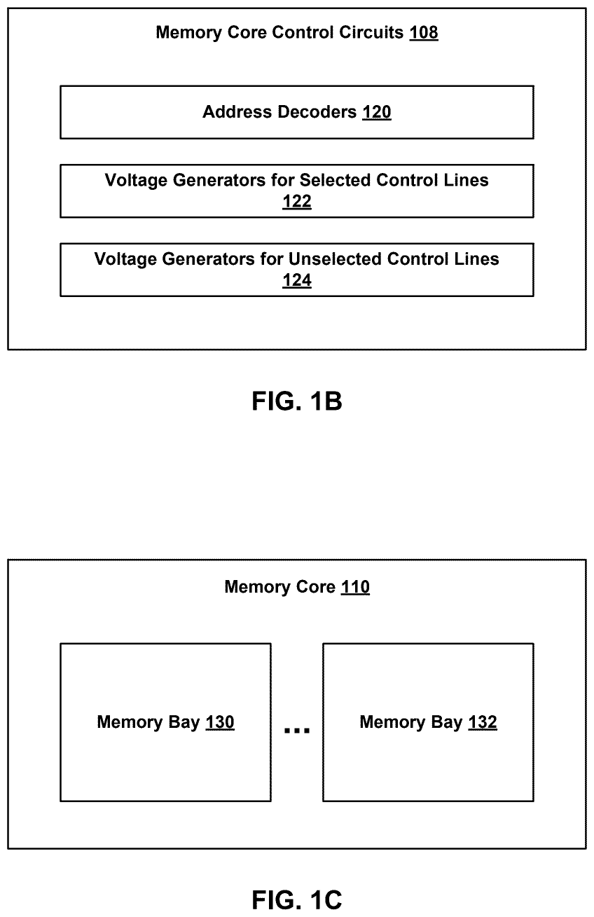

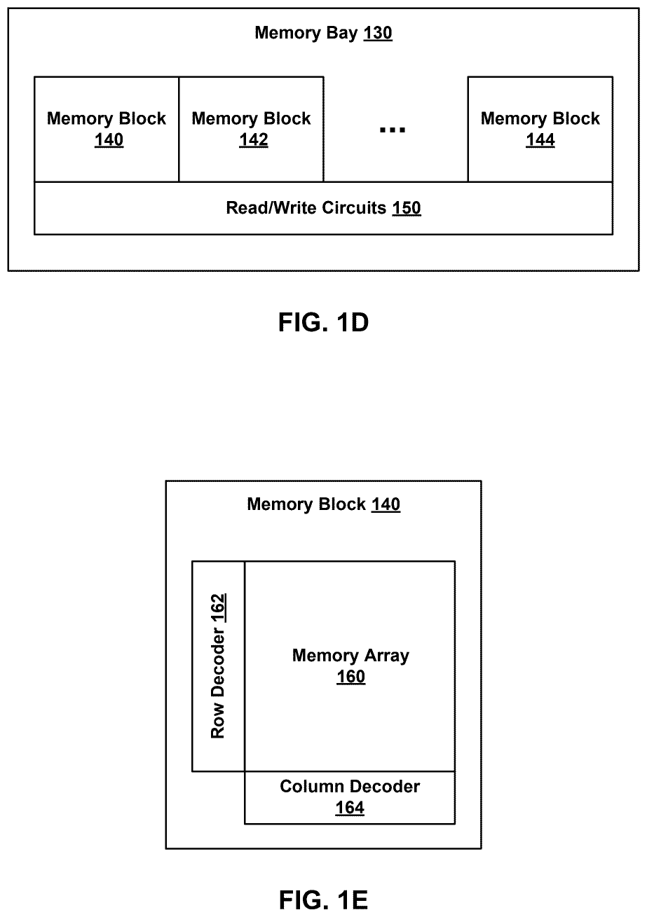

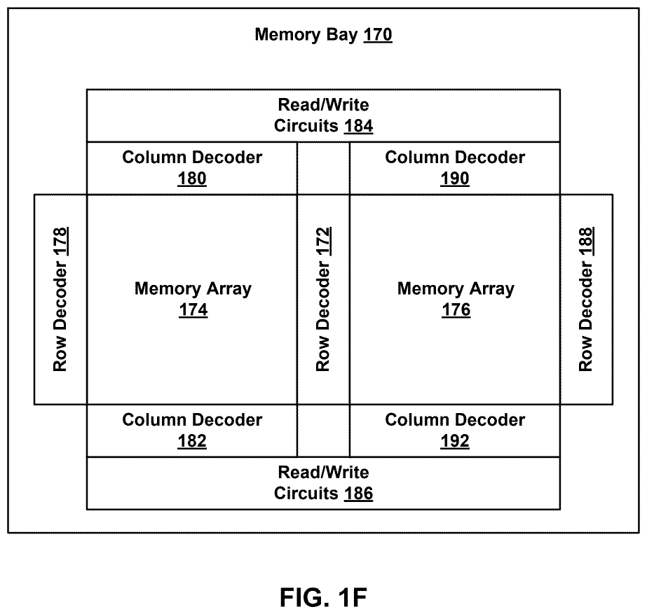

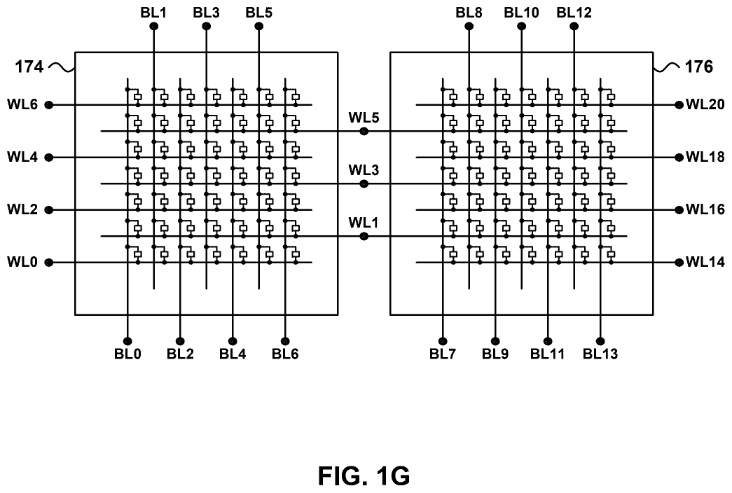

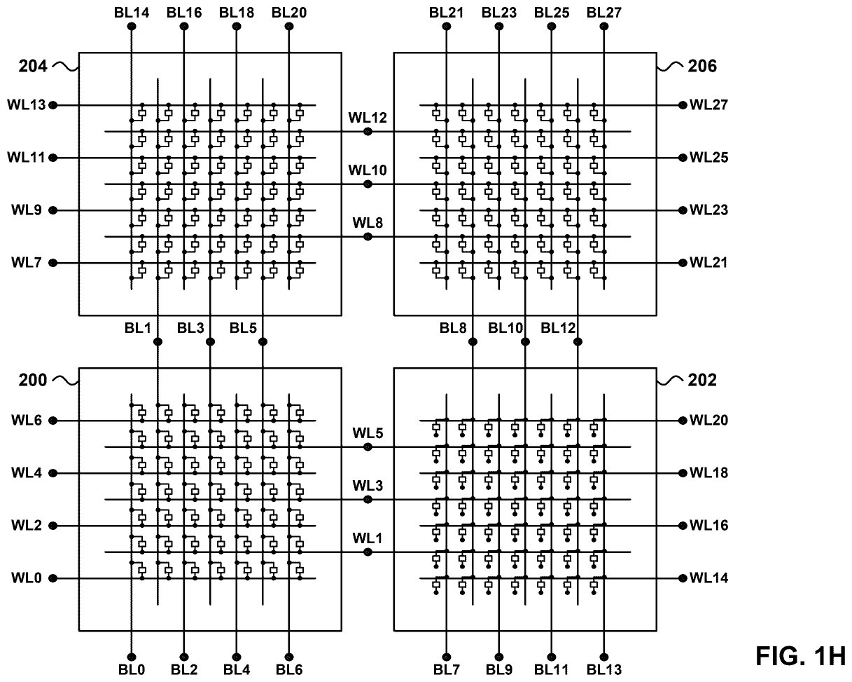

FIG. 1A depicts one embodiment of a memory system 100 and a host 102. Memory system 100 may include a non-volatile storage system interfacing with host 102 (e.g., a mobile computing device or a server). In some cases, memory system 100 may be embedded within host 102. As examples, memory system 100 may be a memory card, a solid-state drive (SSD) such a high density MLC SSD (e.g., 2-bits/cell or 3-bits/cell) or a high performance SLC SSD, or a hybrid HDD/SSD drive.

As depicted, memory system 100 includes a memory chip controller 104 and a memory chip 106. Memory chip 106 may include volatile memory and/or non-volatile memory. Although a single memory chip is depicted, memory system 100 may include more than one memory chip. Memory chip controller 104 may receive data and commands from host 102 and provide memory chip data to host 102.

Memory chip controller 104 may include one or more of control circuitry, state machines, page registers, SRAM, decoders, sense amplifiers, read/write circuits, and/or controllers, or any combination thereof, for controlling the operation of memory chip 106. The one or more control circuitry, state machines, page registers, SRAM, decoders, sense amplifiers, read/write circuits, and/or controllers for controlling the operation of the memory chip may be referred to as managing or control circuits. The managing or control circuits may facilitate one or more memory array operations including forming, erasing, programming, or reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit or arranged on a single die. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of memory cells and/or one or more three-dimensional arrays of memory cells. In an embodiment, memory core may include re-writable memory cells, one-time programmable memory cells, and/or multi-time programmable memory cells, or any combination thereof.

In an embodiment, memory core control circuits 108 and memory core 110 may be arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 may send to memory chip controller 104 both a write command and the data to be written.

Memory chip controller 104 may buffer data to be written and may generate error correction code (ECC) data corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 may control operation of memory chip 106. In an example, before issuing a write operation to memory chip 106, memory chip controller 104 may check a status register to make sure that memory chip 106 is able to accept the data to be written.

In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested.

Once memory chip controller 104 initiates a read or write operation, memory core control circuits 108 may generate appropriate bias voltages and/or currents for word lines and bit lines within memory core 110, as well as generate the appropriate memory block, row, and column addresses.

FIG. 1B depicts an embodiment of memory core control circuits 108. In an embodiment, memory core control circuits 108 include address decoders 120, voltage generators for selected control lines 122, and voltage generators for unselected control lines 124. Control lines may include word lines, bit lines, or a combination of word lines and bit lines. Selected control lines may include selected word lines or selected bit lines that are used to place memory cells into a selected state. Unselected control lines may include unselected word lines or unselected bit lines that are used to place memory cells into an unselected state.

Voltage generators (or voltage regulators) for selected control lines 122 may include one or more voltage generators for generating selected control line voltages. Voltage generators for unselected control lines 124 may include one or more voltage generators for generating unselected control line voltages. Address decoders 120 may generate memory block addresses, as well as row addresses and column addresses for a particular memory block.

FIGS. 1C-1F depict one embodiment of a memory core organization that includes a memory core 110 having multiple memory bays, and each memory bay having multiple memory blocks. Although a memory core organization is disclosed where memory bays include memory blocks, and memory blocks include a group of memory cells, other organizations or groupings also can be used with the technology described herein.

FIG. 1C depicts an embodiment of memory core 110 of FIG. 1A. As depicted, memory core 110 includes memory bay 130 and memory bay 132. In some embodiments, the number of memory bays per memory core can be different for different implementations. For example, a memory core may include only a single memory bay or multiple memory bays (e.g., 16 memory bays, 256 memory bays, etc.).

FIG. 1D depicts one embodiment of memory bay 130 of FIG. 1C. As depicted, memory bay 130 includes memory blocks 140-144 and read/write circuits 150. In some embodiments, the number of memory blocks per memory bay may be different for different implementations. For example, a memory bay may include one or more memory blocks (e.g., 32 memory blocks per memory bay).

Read/write circuits 150 include circuitry for reading and writing memory cells within memory blocks 140-144. As depicted, read/write circuits 150 may be shared across multiple memory blocks within a memory bay. This allows chip area to be reduced because a single group of read/write circuits 150 may be used to support multiple memory blocks. However, in some embodiments, only a single memory block may be electrically coupled to read/write circuits 150 at a particular time to avoid signal conflicts.

In some embodiments, read/write circuits 150 may be used to write one or more pages of data into memory blocks 140-144 (or into a subset of the memory blocks). The memory cells within memory blocks 140-144 may permit direct over-writing of pages (i.e., data representing a page or a portion of a page may be written into memory blocks 140-144 without requiring an erase or reset operation to be performed on the memory cells prior to writing the data).

FIG. 1E depicts one embodiment of memory block 140 of FIG. 1D. As depicted, memory block 140 includes a memory array 160, a row decoder 162, and a column decoder 164. Memory array 160 may include a contiguous group of memory cells having contiguous word lines and bit lines. Memory array 160 may include one or more layers of memory cells, and may include a two-dimensional memory array and/or a three-dimensional memory array.

Row decoder 162 decodes a row address and selects a particular word line in memory array 160 when appropriate (e.g., when reading or writing memory cells in memory array 160). Column decoder 164 decodes a column address and selects a particular group of bit lines in memory array 160 to be electrically coupled to read/write circuits, such as read/write circuits 150 of FIG. 1D. In an embodiment, the number of word lines is 4K per memory layer, the number of bit lines is 1K per memory layer, and the number of memory layers is 4, providing a memory array 160 containing 16M memory cells. Other numbers of word lines per layer, bit lines per layer, and number of layers may be used.

FIG. 1F depicts an embodiment of a memory bay 170. Memory bay 170 is an example of an alternative implementation for memory bay 130 of FIG. 1D. In some embodiments, row decoders, column decoders, and read/write circuits may be split or shared between memory arrays. As depicted, row decoder 172 is shared between memory arrays 174 and 176, because row decoder 172 controls word lines in both memory arrays 174 and 176 (i.e., the word lines driven by row decoder 172 are shared).

Row decoders 178 and 172 may be split such that even word lines in memory array 174 are driven by row decoder 178 and odd word lines in memory array 174 are driven by row decoder 172. Column decoders 180 and 182 may be split such that even bit lines in memory array 174 are controlled by column decoder 182 and odd bit lines in memory array 174 are driven by column decoder 180.

The selected bit lines controlled by column decoder 180 may be electrically coupled to read/write circuits 184. The selected bit lines controlled by column decoder 182 may be electrically coupled to read/write circuits 186. Splitting the read/write circuits into read/write circuits 184 and 186 when the column decoders are split may allow for a more efficient layout of the memory bay.

Row decoders 188 and 172 may be split such that even word lines in memory array 176 are driven by row decoder 188 and odd word lines in memory array 176 are driven by row decoder 172. Column decoders 190 and 192 may be split such that even bit lines in memory array 176 are controlled by column decoder 192 and odd bit lines in memory array 176 are driven by column decoder 190.

The selected bit lines controlled by column decoder 190 may be electrically coupled to read/write circuits 184. The selected bit lines controlled by column decoder 192 may be electrically coupled to read/write circuits 186. Splitting the read/write circuits into read/write circuits 184 and 186 when the column decoders are split may allow for a more efficient layout of the memory bay.

FIG. 1G depicts an embodiment of a schematic diagram (including word lines and bit lines) corresponding with memory bay 170 in FIG. 1F. As depicted, word lines WL1, WL3, and WL5 are shared between memory arrays 174 and 176 and controlled by row decoder 172 of FIG. 1F. Word lines WL0, WL2, WL4, and WL6 are driven from the left side of memory array 174 and controlled by row decoder 178 of FIG. 1F. Word lines WL14, WL16, WL18, and WL20 are driven from the right side of memory array 176 and controlled by row decoder 188 of FIG. 1F.

Bit lines BL0, BL2, BL4, and BL6 are driven from the bottom of memory array 174 and controlled by column decoder 182 of FIG. 1F. Bit lines BL1, BL3, and BL5 are driven from the top of memory array 174 and controlled by column decoder 180 of FIG. 1F. Bit lines BL7, BL9, BL11, and BL13 are driven from the bottom of memory array 176 and controlled by column decoder 192 of FIG. 1F. Bit lines BL8, BL10, and BL12 are driven from the top of memory array 176 and controlled by column decoder 190 of FIG. 1F.

In an embodiment, memory arrays 174 and 176 may include memory layers that are oriented in a plane that is horizontal to the supporting substrate. In another embodiment, memory arrays 174 and 176 may include memory layers that are oriented in a plane that is vertical with respect to the supporting substrate (i.e., the vertical plane is substantially perpendicular to the supporting substrate). In this case, the bit lines of the memory arrays may include substantially vertical bit lines.

FIG. 1H depicts one embodiment of a schematic diagram (including word lines and bit lines) corresponding with a memory bay arrangement wherein word lines and bit lines are shared across memory blocks, and both row decoders and column decoders are split. Sharing word lines and/or bit lines helps to reduce layout area because a single row decoder and/or column decoder can be used to support two memory arrays.

As depicted, word lines WL1, WL3, and WL5 are shared between memory arrays 200 and 202. Bit lines BL1, BL3, and BL5 are shared between memory arrays 200 and 204. Word lines WL8, WL10, and WL12 are shared between memory arrays 204 and 206. Bit lines BL8, BL10, and BL12 are shared between memory arrays 202 and 206.

Row decoders are split such that word lines WL0, WL2, WL4, and WL6 are driven from the left side of memory array 200 and word lines WL1, WL3, and WL5 are driven from the right side of memory array 200. Likewise, word lines WL7, WL9, WL11, and WL13 are driven from the left side of memory array 204 and word lines WL8, WL10, and WL12 are driven from the right side of memory array 204.

Column decoders are split such that bit lines BL0, BL2, BL4, and BL6 are driven from the bottom of memory array 200 and bit lines BL1, BL3, and BL5 are driven from the top of memory array 200. Likewise, bit lines BL7, BL9, BL11, and BL13 are driven from the bottom of memory array 202 and bit lines BL8, BL10, and BL12 are driven from the top of memory array 202. Splitting row and/or column decoders also helps to relieve layout constraints (e.g., the column decoder pitch can be relieved by 2× since the split column decoders need only drive every other bit line instead of every bit line).

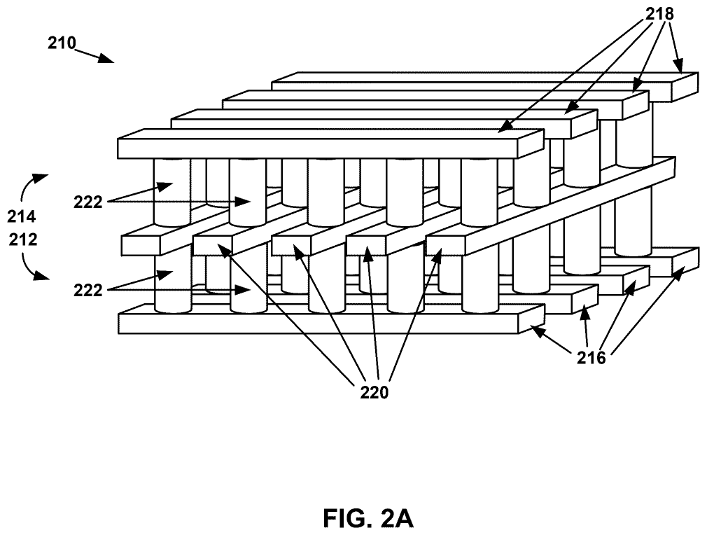

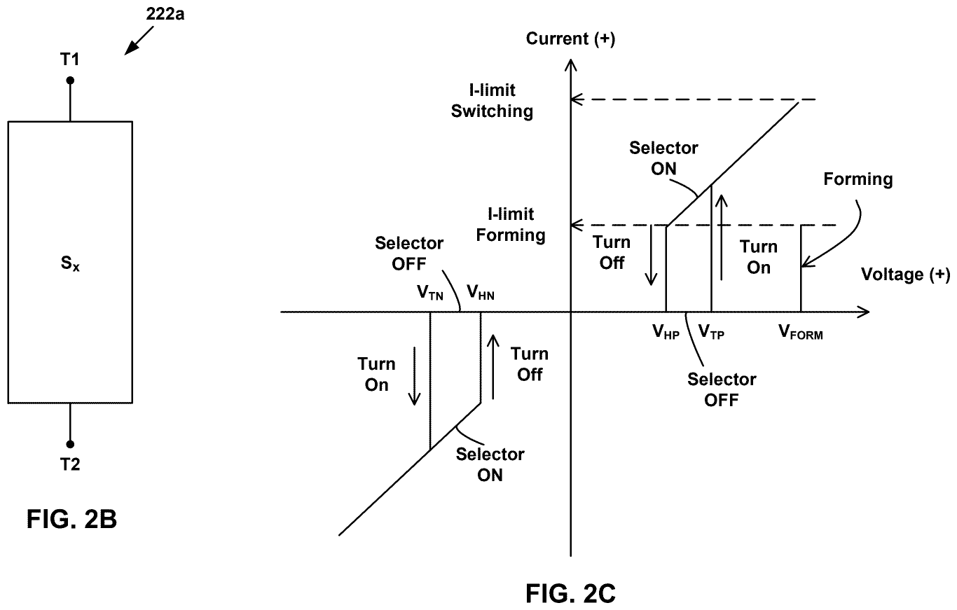

FIG. 2A depicts an embodiment of a portion of a monolithic three-dimensional memory array 210 that includes a first memory level 212, and a second memory level 214 positioned above first memory level 212. Memory array 210 is an example of an implementation of memory array 160 in FIG. 1E. Word lines 216 and 218 are arranged in a first direction and bit lines 220 are arranged in a second direction perpendicular to the first direction. As depicted, the upper conductors of first memory level 212 may be used as the lower conductors of second memory level 214. In a memory array with additional layers of memory cells, there would be corresponding additional layers of bit lines and word lines.

Memory array 210 includes memory cells 222. In embodiments, memory cells 222 may include re-writeable memory cells, one-time programmable memory cells, and multi-time programmable memory cells. In an embodiment, each of memory cells 222 are vertically-oriented. Memory cells 222 may include non-volatile memory cells or volatile memory cells. With respect to first memory level 212, a first portion of memory cells 222 are between and connect to word lines 216 and bit lines 220. With respect to second memory level 214, a second portion of memory cells 222 are between and connect to word lines 218 and bit lines 220.

In an embodiment, each memory cell 222 includes a threshold selector device, where each memory cell 222 represents one bit of data. FIG. 2B is a simplified schematic diagram of a memory cell 222a, which is one example implementation of memory cells 222 of FIG. 2A. In an embodiment, memory cell 222a includes a selector element Sₓ coupled between a first terminal T1 and a second terminal T2. In an embodiment, memory cell 222a is vertically-oriented.

In an embodiment, memory cell 222a is a Threshold Selector Memory Cell—a memory cell that includes a threshold selector device (selector element Sₓ) as both a memory element and a selector device, and stores data using threshold voltage differences of the threshold selector device. In an embodiment, memory cell 222a is operated as a Threshold Selector Memory Cell in which selector element Sₓ may be configured to have either of two different threshold voltages (e.g., a first threshold voltage and a second threshold voltage) to store information. For simplicity, the remaining discussion will refer to memory cell 222a of FIG. 2B as Threshold Selector Memory Cell 222a.

In an embodiment, selector element Sₓ includes a selector material that provides a bidirectional current flow when the current or voltage exceeds a threshold value. Selector element Sₓ is thus also referred to in the remaining description as “threshold selector device Sₓ.” Threshold selector device Sₓ is thus a bidirectional device which permits bidirectional current flow when the current or voltage exceeds a threshold value and blocks current flow when the current or voltage is below the threshold value.

In an embodiment, threshold selector device Sₓ includes an ovonic threshold switch material that allows flow of electrical current only when a voltage differential thereacross exceeds a threshold voltage value. In an embodiment, the ovonic threshold switch material can include a chalcogenide material. The chalcogenide material may include one or more of a GeSeAs alloy, a GeSeAsTe alloy, a GeTeAs alloy, a GeSeTe alloy, a GeSe alloy, a SeAs alloy, a AsTe alloy, a GeTe alloy, a SiTe alloy, a SiAsTe alloy, and a SiAsSe alloy. The chalcogenide material may be undoped or doped with at least one of N, O, C, P, Ge, As, Te, Se, In, or Si.

Although not shown in FIG. 2B, threshold selector device Sₓ also may include one or more electrically conductive and/or barrier layers, such as tungsten, tungsten nitride, tantalum, tantalum nitride, a carbon-nitrogen layer, etc.). The electrically conductive and/or barrier layers may be located above and/or below the ovonic threshold switch material.

FIG. 2C is a diagram depicting example current-voltage (I-V) characteristics of a threshold selector device Sₓ. Each threshold selector device Sₓ is initially in a high resistance (OFF) state. To operate threshold selector device Sₓ as a threshold switch, an initial forming operation may be necessary so that threshold selector device Sₓ operates in a current range in which switching can occur.

For example, a forming operation may include applying to threshold selector device Sₓ one or more voltage pulses each having a magnitude greater than or equal to a forming voltage V_{FORM}. Following the forming operation, threshold selector device Sₓ may be switched ON and OFF, and may be used as either a unipolar or a bipolar threshold selector device. Accordingly, threshold selector device Sₓ may be referred to as a bipolar threshold selector device.

In the example I-V characteristics of FIG. 2C, for positive applied voltages, threshold selector device Sₓ remains in a high resistance state (HRS) (e.g., OFF) until the voltage across the device meets or exceeds (i.e., is more positive than) a first threshold voltage, V_{TP}, at which point threshold selector device Sₓ switches to a low resistance state (LRS) (e.g., ON). Threshold selector device Sₓ remains turned ON until the voltage across the device drops to or below a first hold voltage, V_{HP}, at which point threshold selector device Sₓ turns OFF.

For negative applied voltages, threshold selector device Sₓ remains in a HRS (e.g., OFF) until the voltage across the device meets or exceeds (i.e., is more negative than) a second threshold voltage, V_{TN}, at which point threshold selector device Sₓ switches to a LRS (e.g., ON). Threshold selector device Sₓ remains turned ON until the voltage across the device increases to or exceeds (i.e., is less negative than) a second hold voltage, V_{HN}, at which point threshold selector device Sₓ turns OFF.

For simplicity, the remaining description will refer to positive threshold voltages for threshold selector device Sₓ. Persons of ordinary skill in the art will understand that the techniques described below similarly apply to negative threshold voltages for threshold selector device Sₓ.

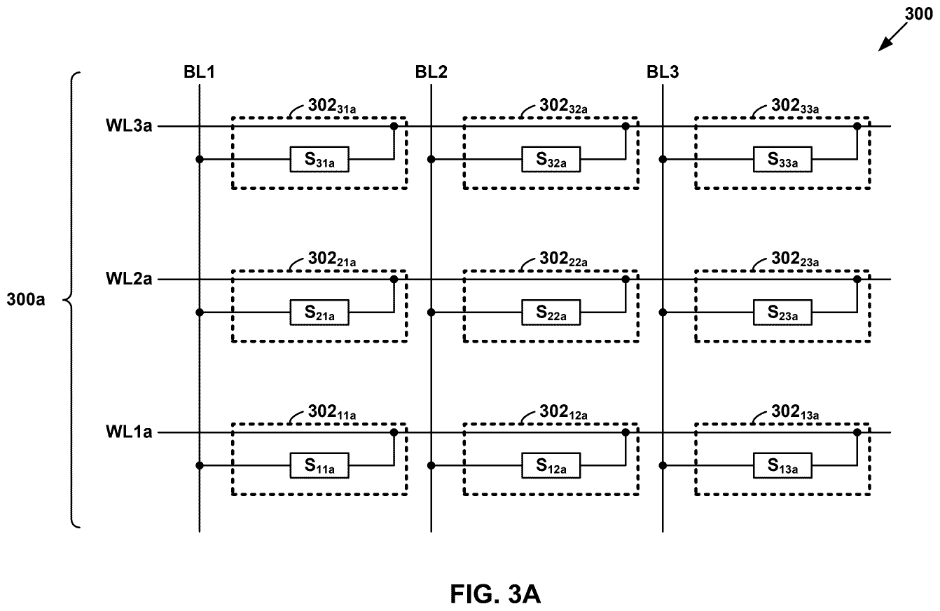

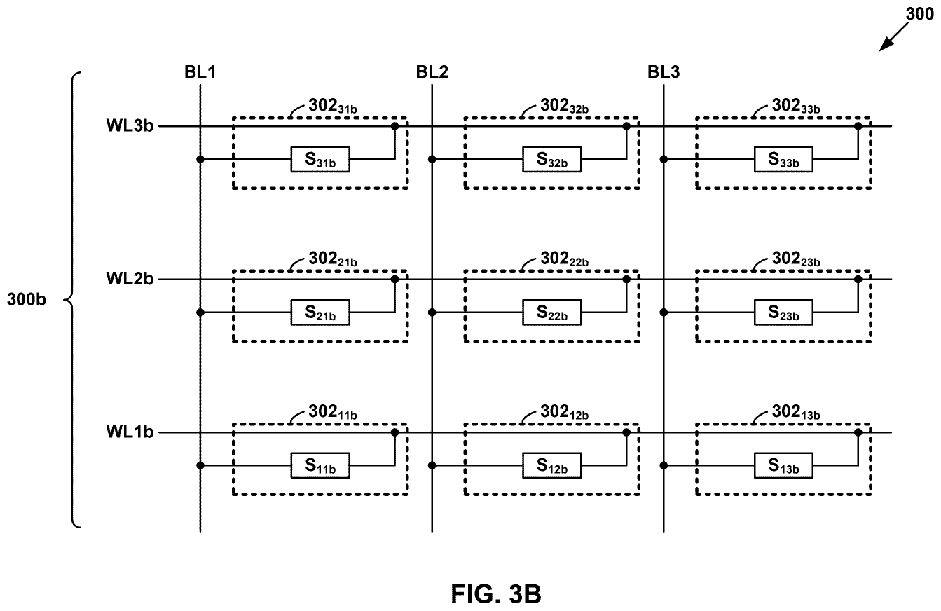

FIGS. 3A-3B are simplified schematic diagrams of an example cross-point memory array 300 which includes a first memory level 300a, and a second memory level 300b positioned above first memory level 300a. Cross-point memory array 300 is an example of an implementation of memory array 160 in FIG. 1E. Cross-point memory array 300 may include more than two memory levels.

Cross-point memory array 300 includes word lines WL1a, WL2a, WL3a, WL1b, WL2b, and WL3b, and bit lines BL1, BL2, and BL3. First memory level 300a includes memory cells 302₁₁ₐ, 302₁₂ₐ, . . . , 302₃₃ₐ coupled to word lines WL1a, WL2a, WL3a and bit lines BL1, BL2, and BL3, and second memory level 300b includes memory cells 302_{11b}, 302_{12b}, . . . , 302_{33b} coupled to word lines WL1b, WL2b, WL3b and bit lines BL1, BL2, and BL3. In an embodiment, each of memory cells 302₁₁ₐ, 302₁₂ₐ, . . . , 302₃₃ₐ are vertically-oriented. In an embodiment, each of memory cells 302_{11b}, 302_{12b}, . . . , 302_{33b} are vertically-oriented.

First memory level 300a is one example of an implementation for first memory level 212 of monolithic three-dimensional memory array 210 of FIG. 2A, and second memory level 300b is one example of an implementation for second memory level 214 of monolithic three-dimensional memory array 210 of FIG. 2A. In an embodiment, each of memory cells 302₁₁ₐ, 302₁₂ₐ, . . . , 302₃₃ₐ, 302_{11b}, 302_{12b}, . . . , 302_{33b}, is a Threshold Selector Memory Cell 222a of FIG. 2B.

Persons of ordinary skill in the art will understand that cross-point memory array 300 may include more or less than six word lines, more or less than three bit lines, and more or less than eighteen memory cells 302₁₁ₐ, 302₁₂ₐ, . . . , 302₃₃ₐ, 302_{11b}, 302_{12b}, . . . , 302_{33b}. In some embodiments, cross-point memory array 300 may include 1000×1000 memory cells, although other array sizes may be used.

Each memory cell 302₁₁ₐ, 302₁₂ₐ, . . . , 302₃₃ₐ, 302_{11b}, 302_{12b}, . . . , 302_{33b} is coupled to one of the word lines and one of the bit lines, and includes a corresponding selector element S₁₁a, S₁₂a, . . . , S₃₃a, S₁₁b, S₁₂b, . . . , S₃₃b, respectively. In an embodiment, each memory cell 302₁₁ₐ, 302₁₂ₐ, . . . , 302₃₃ₐ, 302_{11b}, 302_{12b}, . . . , 302_{33b} is a Threshold Selector Memory Cell 222a in which selector elements S₁₁a, S₁₂a, . . . , S₃₃a, S₁₁b, S₁₂b, . . . , S₃₃b, respectively may be programmed to two different threshold voltages (e.g., a high threshold voltage and a low threshold voltage) to store information.

Each memory cell 302₁₁ₐ, 302₁₂ₐ, . . . , 302₃₃ₐ has a first terminal coupled to one of bit lines BL1, BL2, BL3, and a second terminal coupled to one of word lines WL1a, WL2a, WL3a, and each memory cell 302_{11b}, 302_{12b}, . . . , 302_{33b} has a first terminal coupled to one of bit lines BL1, BL2, BL3, and a second terminal coupled to one of word lines WL1b, WL2b, WL3b. For example, memory cell 30213a includes selector element S₁₃a, and includes a first terminal coupled to bit line BL3, and a second terminal coupled to word line WL1a.

Likewise, memory cell 30222b includes selector element S₂₂b, and includes a first terminal coupled to bit line BL2, and a second terminal coupled to word line WL2b. Similarly, memory cell 302₃₃ₐ includes selector element S₃₃a, and includes a first terminal coupled to bit line BL3, and a second terminal coupled to word line WL3a.

Referring again to FIG. 2B, Threshold Selector Memory Cell 222a includes threshold selector device Sₓ, such as a threshold selector device that includes an ovonic threshold switch material, that has a threshold voltage that varies based on the polarity of the applied voltage previously used to write the threshold selector device Sₓ.

In an embodiment, a threshold selector device Sₓ has a first (e.g., SET) threshold voltage (referred to herein as “SET threshold voltage V_{TS}”) and a second (e.g., RESET) threshold voltage (referred to herein as “RESET threshold voltage V_{TR}”). Thus, the two threshold voltages may be used to represent stored data, with the “memory” being the difference between RESET threshold voltage V_{TR} and SET threshold voltage V_{TS}.

In an embodiment, the SET threshold voltage V_{TS} (e.g., 3V) of the threshold selector device Sₓ represents a first memory state (e.g., SET or “0”) of the Threshold Selector Memory Cell 222a, and the RESET threshold voltage V_{TR} (e.g., 4V) of the threshold selector device Sₓ represents a second memory state (e.g., RESET or “1”) of the Threshold Selector Memory Cell 222a.

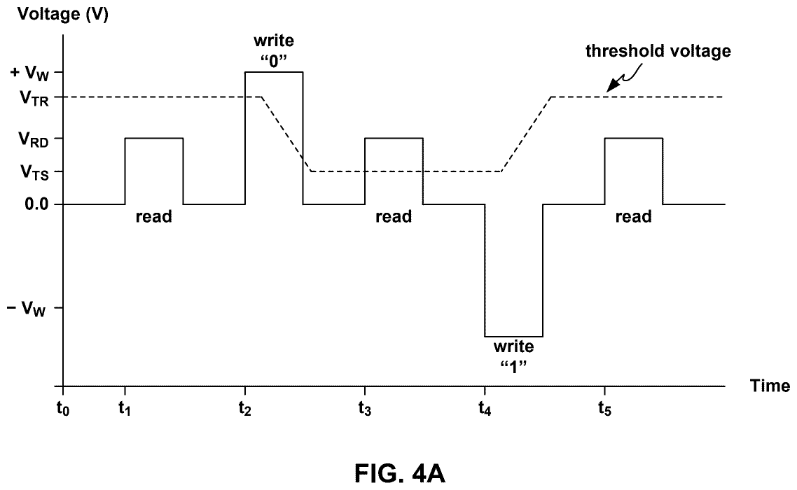

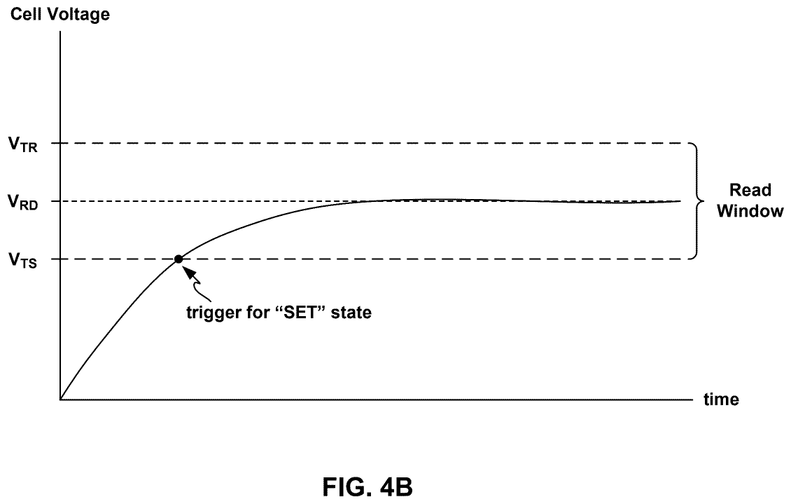

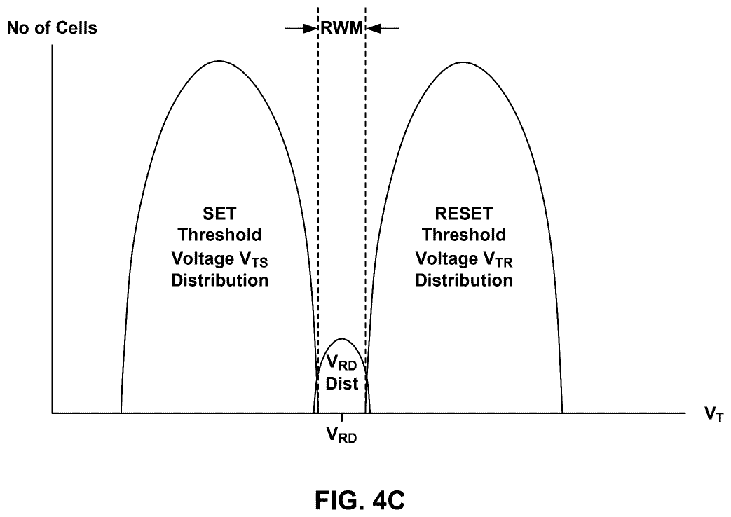

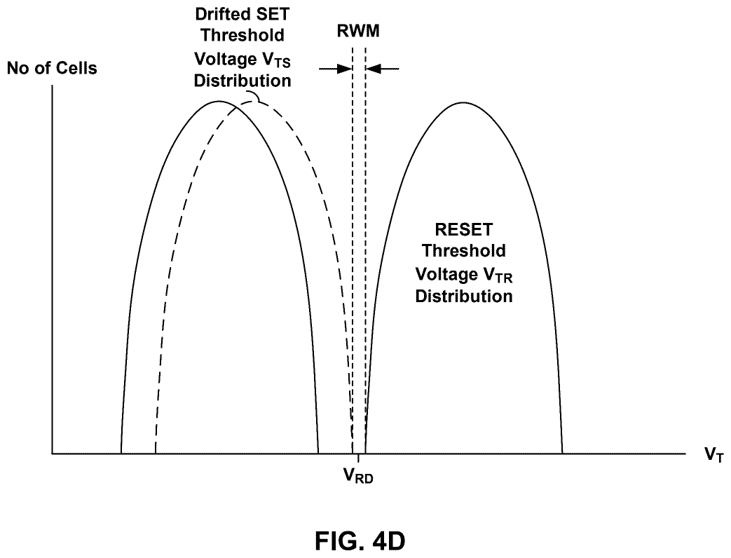

FIG. 4A depicts a simplified diagram of a threshold voltage of a threshold selector device Sₓ versus time, and also depicts read and write voltages applied across a Threshold Selector Memory Cell 222a that includes threshold selector device Sₓ. For simplicity, the following discussion assumes that at time to, Threshold Selector Memory Cell 222a is in second memory state (RESET) and threshold selector device Sₓ has a RESET threshold voltage V_{TR} (4V). In embodiments, a sense amp determines the state of Threshold Selector Memory Cell 222a after allowing sufficient time for stabilization following an initial current spike.

At time t₁, a read voltage V_{RD} (e.g., 3.5V) is applied across Threshold Selector Memory Cell 222a. Read voltage V_{RD} is less than RESET threshold voltage V_{TR} (4V), and thus threshold selector device Sₓ does not switch and does not conduct current, indicating that Threshold Selector Memory Cell 222a is in second memory state (RESET).

At time t₂, a positive write voltage +V_{W} (e.g., +4.5V) is applied across Threshold Selector Memory Cell 222a. In an embodiment, positive write voltage +V_{W} has a same polarity as read voltage V_{RD}, which causes the threshold voltage of threshold selector device Sₓ to go to SET threshold voltage V_{TS} (3V).

At time t₃, read voltage V_{RD} (3.5V) is applied across Threshold Selector Memory Cell 222a. Read voltage V_{RD} is higher than SET threshold voltage V_{TS} (3V), and thus threshold selector device Sₓ and conduct currents, indicating that Threshold Selector Memory Cell 222a is in first memory state (SET).

At time t₄, a negative write voltage −V_{W} (e.g., −4.5V) is applied across Threshold Selector Memory Cell 222a. In an embodiment, negative write voltage −V_{W} has an opposite polarity as read voltage V_{RD}, which causes the threshold voltage threshold selector device Sₓ to go to RESET threshold voltage V_{TR} (4V).

At time t₅, read voltage V_{RD} (3.5V) is applied across Threshold Selector Memory Cell 222a. Read voltage V_{RD} is less than RESET threshold voltage V_{TR} (4V), and thus threshold selector device Sₓ does not switch and does not conduct current, indicating that Threshold Selector Memory Cell 222a is in second memory state (RESET).

Thus, as described above and depicted in FIG. 4A, threshold selector device Sₓ of Threshold Selector Memory Cell 222a has a threshold voltage that differs based on the polarity of applied voltage when writing the memory cell. This example read technique is sometimes referred to as “demarcation read,” and FIG. 4B depicts Threshold Selector Memory Cell 222a voltage versus time for such a demarcation read.

The example of FIGS. 4A-4B depict threshold selector device Sₓ as having a RESET threshold voltage V_{TR} and a SET threshold voltage V_{TS}. A memory array (such as memory array 160 of FIG. 1E) typically includes many Threshold Selector Memory Cells 222a, each including a corresponding threshold selector device Sₓ.

Ideally, the threshold selector devices Sₓ in the memory array have the same RESET threshold voltage V_{TR} and SET threshold voltage V_{TS}, but in reality a population of threshold selector devices Sₓ will have a first distribution of SET threshold voltage V_{TS} values and a second distribution of RESET threshold voltage V_{TR} values.

Thus a first selector device Sₓ₁ will have a first (SET) threshold voltage and a second (RESET) threshold voltage, a second selector device Sₓ₂ will have a third (SET) threshold voltage and a fourth (RESET) threshold voltage. The first distribution of SET threshold voltage V_{TS} values includes first (SET) threshold voltage and third (SET) threshold voltage, and the second distribution of RESET threshold voltage V_{TR} values includes second (RESET) threshold voltage and fourth (RESET) threshold voltage.

FIG. 4C is a diagram depicting an example SET threshold voltage V_{TS} distribution, an example RESET threshold voltage V_{TR} distribution, and an example read voltage V_{RD} distribution for a population of Threshold Selector Memory Cells 222a including threshold selector devices Sₓ.

In embodiments, each distribution has a lower tail and an upper tail. A difference between the upper tail of the SET threshold voltage V_{TS} distribution and the lower tail of the RESET threshold voltage V_{TR} distribution is referred to herein as the read window margin (RWM), and the read voltage V_{RD} (which has a read voltage V_{RD} distribution) is ideally selected within the read window margin.

In embodiments, a read error occurs if read voltage V_{RD} is applied across a Threshold Selector Memory Cell 222a that is in the first memory state (SET), but the threshold selector device Sₓ does not switch and does not conduct current or if read voltage V_{RD} is applied across a Threshold Selector Memory Cell 222a that is in the second memory state (RESET), but the threshold selector device Sₓ switches and conducts current. A required read reliability set by a read bit error rate (BER) specification determines the read window margin requirements for a memory array of Threshold Selector Memory Cells 222a.

One phenomenon of threshold selector devices Sₓ, such as threshold selector devices that include an ovonic threshold switch material, is that following a write operation, the SET threshold voltage V_{TS} and RESET threshold voltage V_{TR} continually increase with time at a rate based on material properties. This is referred to herein as threshold voltage drift. The threshold voltage drift also has a distribution and may be different for SET threshold voltage V_{TS} and RESET threshold voltage V_{TR}.

A demarcation read must allow for reduced read window margin assuming maximum SET threshold voltage V_{TS} drift and zero RESET threshold voltage V_{TR} drift. This is because it is difficult track how much the threshold voltage of a Threshold Selector Memory Cell 222a may have drifted. The maximum drift may be bounded by “refreshing” a Threshold Selector Memory Cell 222a at a defined time interval which is determined based on performance impact. A refresh involves a read followed by a write of the Threshold Selector Memory Cell 222a.

Taking threshold voltage drift into account reduces read window margin significantly. FIG. 4D shows the impact of threshold voltage drift on the available read window for reading at a target product read BER. In particular, the diagram depicts the original SET threshold voltage V_{TS} distribution, the drifted SET threshold voltage V_{TS} distribution after time T, and the RESET threshold voltage V_{TR} distribution with no drift.

Comparing FIGS. 4C and 4D, the shrinking read window margin as a result of threshold voltage drift makes demarcation read very challenging. One approach to addressing threshold voltage drift is to look for materials with a large nominal read window margin, low drift and a circuit design with very tight V_{RD} distribution, but these techniques are costly and may still be insufficient to achieve a necessary product read BER.

Technology is described for reading Threshold Selector Memory Cells (such as Threshold Selector Memory Cell 222a of FIG. 2B) by using “Reference Memory Cells” for tracking and mitigating threshold voltage drift in “Data Memory Cells.” In an embodiment, Data Memory Cells and Reference Memory Cells are each Threshold Selector Memory Cell 222a that have a same physical structure and are substantially identical within the limits of semiconductor fabrication technology.

As used herein, Data Memory Cells are Threshold Selector Memory Cells (such as Threshold Selector Memory Cell 222a of FIG. 2B) that each include a threshold selector device Sₓ having a RESET threshold voltage V_{TR} (V_{TRD}) and a SET threshold voltage V_{TS} (V_{TSD}) and that are used to store a data bit.

As used herein, a Reference Memory Cell is a Threshold Selector Memory Cells (such as Threshold Selector Memory Cell 222a of FIG. 2B) that includes a threshold selector device Sₓ having a SET threshold voltage V_{TS} (V_{TSR}) and a RESET threshold voltage V_{TR} (V_{TRR}), In embodiments, the Reference Memory Cell is used to store a reference bit (e.g., either “0” (SET) or “1” (RESET).

In an embodiment, one Reference Memory Cell is used to track threshold voltage drift of N corresponding Data Memory Cells, where N=1, 2, 3, . . . . In an embodiment, N=128, although other values of N may be used. For simplicity, the following discussion assumes that N=128.

In an embodiment, each time data are written to the Data Memory Cells, a predetermined value (e.g., 0 or 1) is written to the corresponding Reference Memory Cell. For simplicity, the following discussion assumes that the predetermined value is 0 (i.e., each time data are written to the Data Memory Cells, the corresponding Reference Memory Cell is written to the SET memory state).

In an embodiment, a Reference Memory Cell having a SET threshold voltage V_{TSR} drifts with time along with the drift of SET threshold voltages V_{TSD} and RESET threshold voltages V_{TRD} of the N corresponding Data Memory Cells. In an embodiment, it is assumed that the rate of drift of the Reference Memory Cell SET threshold voltage V_{TSR} is substantially the same as the rate of drift of the Data Memory Cell SET threshold voltages V_{TSD} and Data Memory Cell RESET threshold voltages V_{TRD}.

In an embodiment, the Reference Memory Cell SET threshold voltage V_{TSR} is detected and used to cancel out the drift components of the Data Memory Cell SET threshold voltages V_{TSD} and Data Memory Cell RESET threshold voltages V_{TRD} when reading the Data Memory Cells. In such an embodiment, the cost and power impact of a single Reference Memory Cell for every N Data Memory Cells is minimal. Such a technique is referred to herein as a threshold voltage reference read technique.

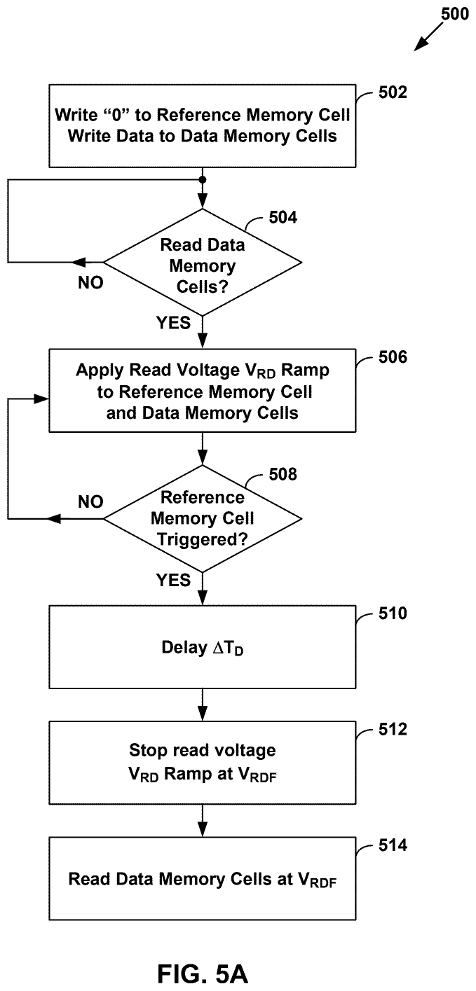

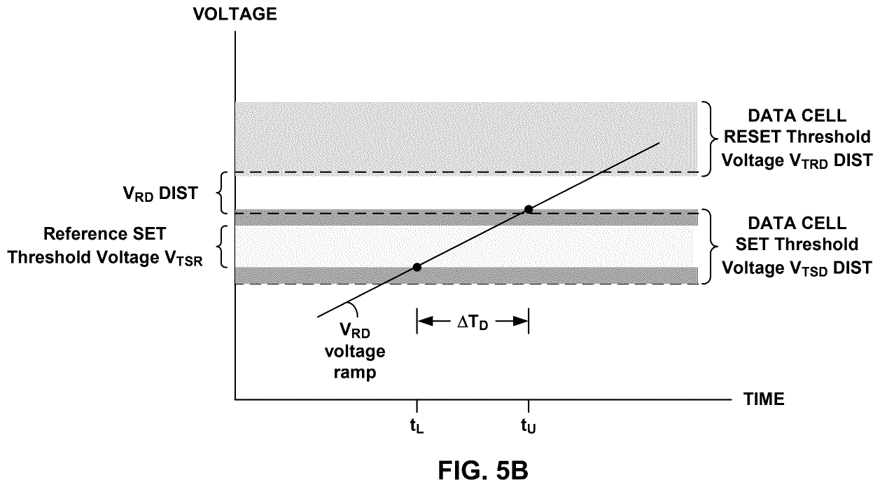

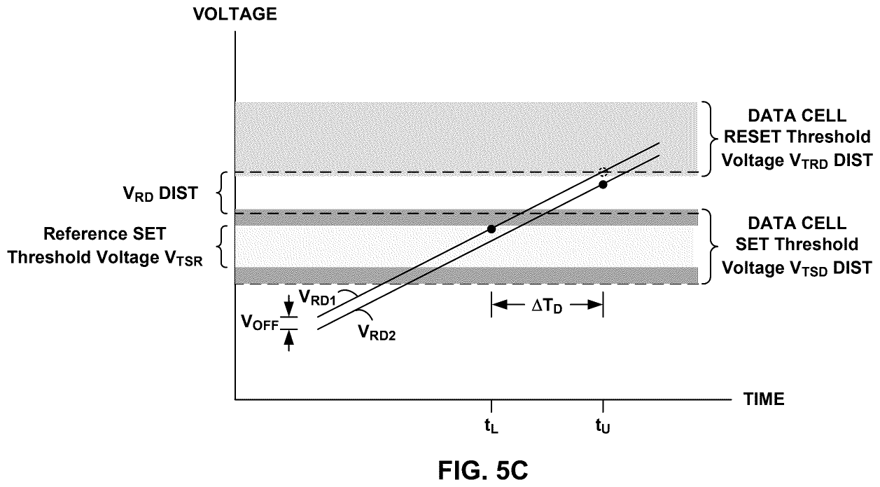

FIG. 5A is a flow diagram of an embodiment of a threshold voltage reference read technique in accordance with this technology. In an embodiment, threshold voltage reference read process 500 is used to read N Data Memory Cells, such as Threshold Selector Memory Cells 222a of FIG. 2B. In an example embodiment, process 500 is performed by one or more of memory chip controller 104 and memory core control circuits 106 of FIG. 1A.

In an embodiment, each time data are written to N Data Memory Cells, the corresponding Reference Memory Cell is written to the first memory state (e.g., 0 or SET). Thus, at step 502, a write signal writes “0” to the Reference Memory Cell and a programming signal writes data to the N Data Memory Cells. For simplicity, the remaining discussion of process 500 will refer to “Data Memory Cells.”

At step 504, a determination is made whether the Data Memory Cells are to be read. If not, process 500 loops back to step 504 and continues to wait for a request to read the Data Memory Cells is received.

In an embodiment, a read request may be received at any time after the Data Memory Cells and Reference Memory Cell are written in step 502. During that time interval the Reference Memory Cell SET threshold voltage V_{TSR} distribution, the Data Memory Cell SET threshold voltage V_{TSD} distribution and the Data Memory Cell RESET threshold voltages V_{TRD} distribution continue to drift.

In an embodiment, it is assumed that the rate of drift of the Reference Memory Cell SET threshold voltage V_{TSR} distribution is substantially the same as the rate of drift of the Data Memory Cell SET threshold voltage V_{TSD} distribution and the Data Memory Cell RESET threshold voltage V_{TRD} distribution.

Eventually, at some time after the Data Memory Cells are written in step 502, a request is received to read the data from the Data Memory Cells. Thus, at step 504, a determination is made that the Data Memory Cells are to be read, process 500 proceeds to step 506, and a ramping read voltage V_{RD} is applied to word lines of the Reference Memory Cell and the Data Memory Cells.

At step 508, a determination is made whether the Reference Memory Cell has triggered. In particular, when the ramping read voltage V_{RD} meets or exceeds the Reference Memory Cell SET threshold voltage V_{TSR}, the threshold selector device Sₓ of the cell will trigger and conduct current. Thus, step 508 determines a value of ramping read voltage V_{RD} that is equal to the Reference Memory Cell SET threshold voltage V_{TSR}.

As described above, it is assumed that the Reference Memory Cell SET threshold voltage V_{TSR} distribution drifts at approximately the same rate as the Data Memory Cell SET threshold voltage V_{TSD} distribution and the Data Memory Cell RESET threshold voltage V_{TRD} distribution. Thus, it is assumed that the value of the drifted Reference Memory Cell SET threshold voltage V_{TSR} determined at step 508 is an indication of the amount of drift of the Data Memory Cell SET threshold voltage V_{TSD} distribution and the Data Memory Cell RESET threshold voltage V_{TRD} distribution.

If at step 508 a determination is made that the Reference Memory Cell has not yet triggered, the process returns to step 506 to continue ramping read voltage V_{RD}. If, however, at step 508 a determination is made that the Reference Memory Cell has triggered, at step 510 process 500 waits a delay time ΔT_{D}.

In particular, FIG. 5B is a diagram depicting an example Reference Memory Cell SET threshold voltage V_{TSR} distribution, and an example Data Memory Cell SET threshold voltage V_{TSD} distribution and Data Memory Cell RESET threshold voltage V_{TRD} distribution at an instant at which Reference Memory Cell has triggered. Thus, FIG. 5B is essentially a “snapshot” of the drifted Reference Memory Cell SET threshold voltage V_{TSR} distribution and the drifted Data Memory Cell SET threshold voltage V_{TSD} distribution and Data Memory Cell RESET threshold voltage V_{TRD} distribution.

The Reference Memory Cell second threshold voltage V_{TSR} distribution is depicted smaller than that of the Data Memory Cell SET threshold voltage V_{TSD} distribution because there are more Data Memory Cells than Reference Memory Cells. The SET threshold voltage V_{TSR} of any particular Reference Memory Cell lies somewhere within the Reference Memory Cell SET threshold voltage V_{TSR} distribution, but the exact location for any particular Reference Memory Cell is unknown.

Thus, also depicted in FIG. 5B is ramping read voltage V_{RD}. In the illustrated example, the ramping read voltage V_{RD} crosses the lower tail of the Reference Memory Cell SET threshold voltage V_{TSR} distribution at time t_{L} and crosses the upper tail of Data Memory Cell SET threshold voltage V_{TSD} distribution at time t_{U}. In an embodiment, data sample delay time ΔT_{D} is set equal to time difference t_{U}−t_{L}.

In other words, first predetermined delay time ΔT_{D} is chosen to allow ramping read voltage V_{RD} to exceed the upper tail of the Data Memory Cell SET threshold voltage V_{TSD} distribution for corresponding Reference Memory Cells having a SET threshold voltage at the lower tail of the Reference Memory Cell SET threshold voltage V_{TSR} distribution. Persons of ordinary skill in the art will understand that other criteria may be used for specifying first predetermined delay time ΔT_{D}.

Referring again to FIG. 5A, after waiting first predetermined delay time ΔT_{D}, at step 512 the read voltage V_{RD} ramp is stopped (e.g., at a value V_{RDF}), and the read voltage V_{RD} is fixed at V_{RDF}.

At step, 514, the N Data Memory Cells are read at read voltage V_{RD}=V_{RDF}. Without wanting to be bound by any particular theory, it is believed that example threshold voltage reference read process 500 of FIG. 5A may reduce the impact of threshold voltage drift on the read window margin of Data Memory Cells (Threshold Selector Memory Cell 222a of FIG. 2B) that each include a threshold selector device Sₓ having a Data Memory Cell RESET threshold voltage V_{TRD} and a Data Memory Cell threshold voltage SET V_{TSD} that are used to store data bits.

A simple example may be used to illustrate an example operation of threshold voltage reference read technique 500 of FIG. 5A. In this example, a first memory cell (the Reference Memory Cell) includes a first two-terminal element (e.g., a first threshold selector device Sₓ) having a first threshold voltage (SET) and a second threshold voltage (RESET). A second memory cell (the Data Memory Cell) includes a second two-terminal element (e.g., a second threshold selector device Sₓ) having a third threshold voltage (SET) and a fourth threshold voltage (RESET).

In an embodiment, a first voltage signal (e.g., a write signal) is applied to the first memory cell to cause the first two-terminal element to have the first threshold voltage (SET), and a second voltage signal (e.g., a programming signal) is applied to the second memory cell to cause the second two-terminal element to have either the third threshold voltage (SET) or the fourth threshold voltage (RESET) (step 502).

A third voltage signal (e.g., read voltage V_{RD}) is applied to the first memory cell and the second memory cell, the third voltage signal increases at a first ramp rate. (step 506).

When the third voltage signal meets of exceeds the first threshold voltage, a determination is made that the first memory cell switches from a non-conducting state to a conducting state (step 508).

The second memory cell is read using the third voltage signal a first predetermined delay time (e.g., first predetermined delay time ΔT_{D}) after the first memory cell switches from the non-conducting state to the conducting state (steps 510 and 514).

In the example threshold voltage reference read process 500 of FIG. 5A, the same ramping read voltage V_{RD} is applied to word lines of both the Reference Memory Cell and the Data Memory Cells. In another embodiment, a first ramping read voltage V_{RD1} is applied to the word line of the Reference Memory Cell and a second ramping read voltage V_{RD2} is applied to word lines of the Data Memory Cells.

For example, FIG. 5C depicts the example threshold voltage distributions of FIG. 5B, with first ramping read voltage V_{RD1} that is applied to the word line of the Reference Memory Cell and second ramping read voltage V_{RD2} that is applied to word lines of the Data Memory Cells. In an embodiment, first ramping read voltage V_{RD1} and second ramping read voltage V_{RD2} have the same ramp rate, but second ramping read voltage V_{RD2} is offset (lower) from first ramping read voltage V_{RD1} by voltage offset VOFF.

In the example of FIG. 5C, the SET threshold voltage V_{TSR} of the particular Reference Memory Cell is higher than that of the SET threshold voltage V_{TSR} depicted in FIG. 5B. As a result, if the same ramping read voltage V_{RD1} were applied to word lines of both the Reference Memory Cell and the Data Memory Cells, and the Data Memory Cells are read after delay time ΔT_{D} at time t_{U}, the read may disturb some Data Memory Cells that have a RESET threshold voltage V_{TRD} at the of Data Memory Cell RESET threshold voltage V_{TRD} distribution (depicted as the circle with a dashed line in FIG. 5C).

If instead second ramping read voltage V_{RD2} that is offset (lower) from first ramping read voltage V_{RD1} is applied to Data Memory Cells, and the Data Memory Cells are read after delay time ΔT_{D} at time t_{U}, the read will not disturb Data Memory Cells that have a RESET threshold voltage V_{TRD} at the of Data Memory Cell RESET threshold voltage V_{TRD} distribution (depicted as the solid circle in FIG. 5C). Without wanting to be bound by any particular theory, it is believed that this technique may be useful in in which the desired delay is less than a minimum time ΔT_{D} imposed by the circuit (because there is some finite time needed to feed back the reference bit information to the data bits).

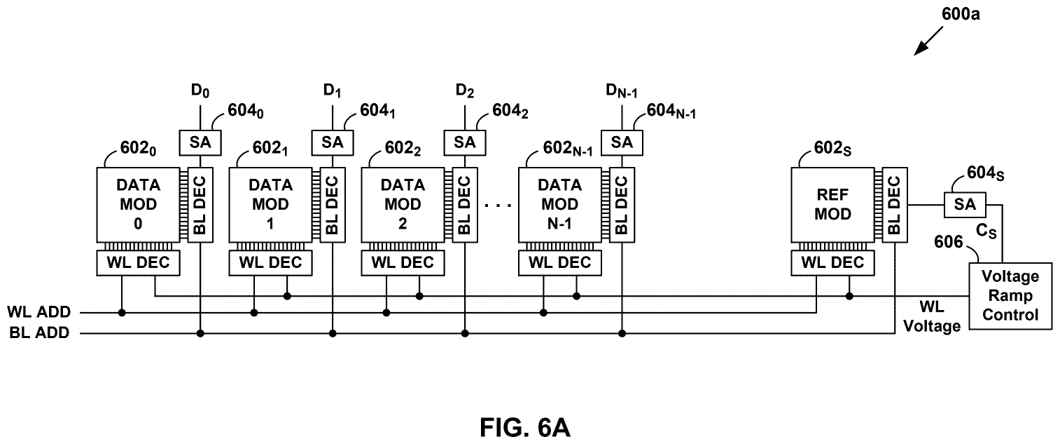

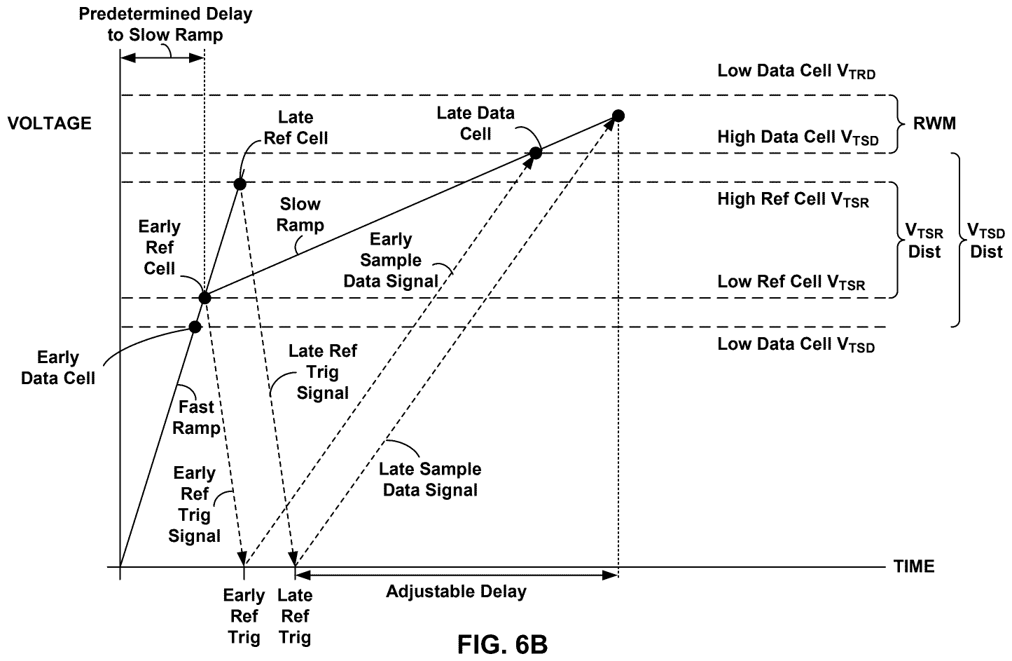

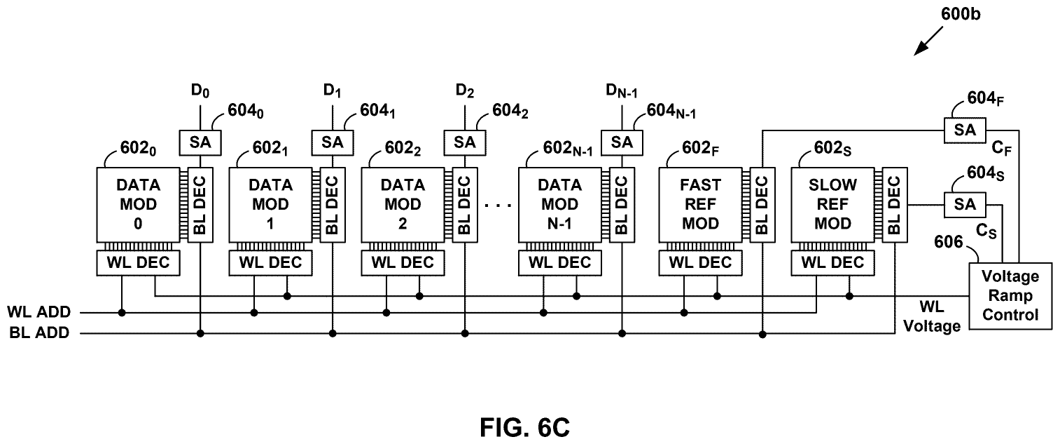

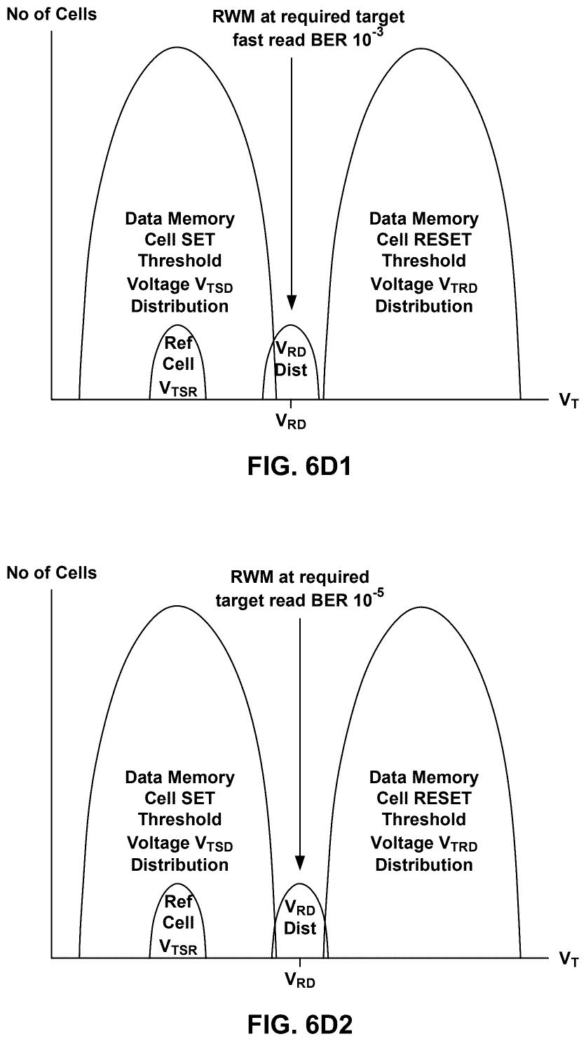

FIG. 6A is a simplified diagram of an embodiment of an threshold voltage reference read system 600a that may be used to implement a threshold voltage reference read process, such as example a threshold voltage reference read process 500 of FIG. 5A. In an embodiment, threshold voltage reference read system 600a may be implemented on example memory chip 106 of FIG. 1A.

In an embodiment, threshold voltage reference read system 600a includes N data modules 602₀, 602₁, 602₂, . . . , 602_{N-1}, and a corresponding reference module 602_{S}. Each of data modules 602₀, 602₁, 602₂, . . . , 602_{N-1} and corresponding reference module 602_{S} is coupled to a corresponding word line decoder WL DEC and a corresponding bit line decoder BL DEC.

Each of data modules 602₀, 602₁, 602₂, . . . , 602_{N-1} and corresponding reference module 602_{S} includes an array of Threshold Selector Memory Cells 222a in which a specific Threshold Selector Memory Cell being accessed (referred to herein as a “Selected Threshold Selector Memory Cell”) is selected using the word line and bit line addresses, WL ADD and BL ADD, respectively.

Each of data modules 602₀, 602₁, 602₂, . . . , 602_{N-1} and corresponding reference module 602_{S} is coupled via the corresponding bit line decoder BL DEC to sense amplifier circuits 604₀, 604₁, 604₂, . . . , 604_{N-1} and 604_{S}, respectively. Sense amplifier circuits 604₀, 604₁, 604₂, . . . , 604_{N-1} are used to determine the memory state of selected Data Memory Cells of data modules 602₀, 602₁, 602₂, . . . , 602_{N-1} and generate data outputs D₀, D₁, D₂, . . . , D_{N-1}, respectively.

In an embodiment, sense amplifier circuit 604s has a first reference output signal C_{S} coupled to a first input terminal of a voltage ramp control circuit 606. In an embodiment, first reference output signal C_{S} has a first value (e.g., LOW) when a word line voltage (WL Voltage) generated by voltage ramp control circuit 606 is less than Reference Memory Cell SET threshold voltage V_{TSR} of the selected Reference Memory Cell of reference module 602_{S}, and has a second value (e.g., HIGH) when WL Voltage is greater than or equal to Reference Memory Cell SET threshold voltage V_{TSR} of the selected Reference Memory Cell of reference module 602_{S}.

In an embodiment, first reference output signal C_{S} is configured to control voltage ramp control circuit 606, which is configured to generate a ramping WL voltage that is applied to the word lines of Selected Threshold Selector Memory Cells. In an embodiment, the WL voltage is used to drive the Selected Threshold Selector Memory Cells in data modules 602₀, 602₁, 602₂, . . . , 602_{N-1} and corresponding reference module 602_{S}

FIG. 6B is a diagram depicting example signals in the example threshold voltage reference read system 600a of FIG. 6A. In an embodiment, the WL voltage ramp is controlled for reference module data modules 602₀, 602₁, 602₂, . . . , 602_{N-1} and corresponding reference module 602_{S} such as shown in FIG. 6B. In particular, FIG. 6B depicts distribution bounds of Data Memory Cell SET threshold voltage V_{TSD} and the lower tail of Data Memory Cell RESET threshold voltage V_{TRD} distribution.

In an embodiment, the read window margin is depicted as the difference between the lower tail of Data Memory Cell RESET threshold voltage V_{TRD} distribution and the upper tail of the Data Memory Cell SET threshold voltage V_{TSD} distribution. In addition, FIG. 6B depicts distribution bounds of Reference Cell SET threshold voltage V_{TSR}.

In example threshold voltage reference read system 600a of FIG. 6A, N data bits are derived from N data modules 602₀, 602₁, 602₂, . . . , 602_{N-1}, each of which has an array of Data Memory Cells from which one is selected for each access. In addition, reference module 602_{S} supplies the corresponding reference bit for each access.

In an embodiment, an access involves selecting and reading one Data Memory Cell from each of N data modules 602₀, 602₁, 602₂, . . . , 602_{N-1} and one corresponding Reference Memory Cell from reference module 602_{S}. Although not depicted in FIG. 6A, a controller (e.g., memory chip controller 104 of FIG. 1A) coordinates the activity across all N data modules 602₀, 602₁, 602₂, . . . , 602_{N-1}, which are collectively referred to herein as a “Bank.”

In addition, any one set of N data bits and the corresponding reference bit is referred to herein as a “line.” In embodiments, it is assumed that any line is first written before it can be read.

In an embodiment, a write operation to a line will update the Data Memory Cells based on user data but will always set the corresponding Reference Memory Cell to the SET memory state. Without wanting to be bound by any particular theory, it is believed that a write operation resets the threshold voltage drift of all the bits in the line (e.g., no drift).

In an embodiment, a read operation starts with a fast-ramping WL Voltage for Data Memory Cells and the corresponding Reference Memory Cell. This is depicted as “Fast Ramp” in FIG. 6B. In an embodiment, after a second predetermined delay time ΔT_{SR}, WL Voltage transitions to a slower ramp depicted as “Slow Ramp” in FIG. 6B. In an embodiment, second predetermined delay time ΔT_{SR} is an estimated time at which the fast ramp crosses the lower tail of the Reference Memory Cell SET threshold voltage V_{TSR}. (designated as an “Early Reference Cell”) in FIG. 6B.

In an embodiment, WL Voltage transitions from Fast Ramp to Slow Ramp to prevent any Data Memory Cells from hitting the lower tail of the Data Memory Cell RESET threshold voltage V_{TRD} distribution and disturbing those Data Memory Cells.

In an embodiment, when the Reference Data Cell triggers (e.g., when WL Voltage ramp meets or exceeds the Reference Memory Cell SET threshold voltage V_{TSR}, the Reference Data Cell sends a signal (depicted as “Ref Trigger Signal” in FIG. 6B) to the controller. In an embodiment, after the controller receives the Ref Trigger Signal, the controller will wait first predetermined delay time ΔT_{D} (step 510 in FIG. 5A) and then stop the WL Voltage ramp, and sense the Data Memory Cells.

In an embodiment, first predetermined delay time ΔT_{D} is selected so that the read of the Data Memory Cells is positioned correctly in the read window to achieve a target BER. In an embodiment, this delay is determined by the Fast and Slow Ramp rates of WL Voltage. In an embodiment, the controller stops the WL Voltage ramp and senses the Data Memory Cells to prevent continued ramp of WL Voltage beyond the lower tail of the Data Memory Cell RESET threshold voltage V_{TRD} distribution.

Without wanting to be bound by any particular theory, it is believed that example threshold voltage reference read system 600a of FIG. 6A may reduce the impact of threshold voltage drift on the read window margin of Data Memory Cells (such as Threshold Selector Memory Cells 222a of FIG. 2B) that each include a threshold selector device Sₓ having a Data Memory Cell RESET threshold voltage V_{TRD} and a Data Memory Cell threshold voltage SET V_{TSD} that are used to store data bits.

The example threshold voltage reference read system 600a uses a single corresponding reference module 602_{S} for N data modules 602₀, 602₁, 602₂, . . . , 602_{N-1}. FIG. 6C is an embodiment of an alternative example threshold voltage reference read system 600b that may be used to implement a threshold voltage reference read process. In an embodiment, threshold voltage reference read system 600b is similar to threshold voltage reference read system 600a of FIG. 6A, but also includes an additional corresponding reference module 602_{F} (also referred to herein as Fast Reference Module 602_{F}) and an additional sense amplifier circuit 604_{F}. Threshold voltage reference read system 600b also includes reference module 602_{S} (also referred to herein as Slow Reference Module 602_{S}).

In an embodiment, sense amplifier circuit 604_{F} has a second reference output signal C_{F} coupled to a second input terminal of a voltage ramp control circuit 606. In an embodiment, second reference output signal C_{F} has a first value (e.g., LOW) when WL Voltage is less than Reference Memory Cell SET threshold voltage V_{TSR} of the selected Reference Memory Cell of Fast Reference Module 602_{F}, and has a second value (e.g., HIGH) when WL voltage is greater than or equal to Reference Memory Cell SET threshold voltage V_{TSR} of the selected Reference Memory Cell of Fast Reference Module 602_{F}.

In an embodiment, first reference output signal C_{S} generated from Slow Reference Module 602_{S} is referred to herein as a “slow read reference bit,” and second reference output signal C_{F} generated from Fast Reference Module 602_{F} is referred to herein as a “fast read reference bit.” In an embodiment, first reference output signal C_{S} and second reference output signal C_{F} are each configured to control voltage ramp control circuit 606, which is configured to generate ramping WL voltage that is applied to the word lines of Selected Threshold Selector Memory Cells in data modules 602₀, 602₁, 602₂, . . . , 602_{N-1}, and reference modules 602_{S} and 602_{F}.

In an embodiment, a write operation to a line will update the Data Memory Cells based on user data but will always set the corresponding Reference Memory Cells of Slow Reference Module 602_{S} and Fast Reference Module 602_{F} to the SET memory state. In contrast to the read operation of threshold voltage reference read system 600a, in an embodiment threshold voltage reference read system 600b includes two different read operations, referred to herein as a “Fast Read” and a “Slow Read.” In an embodiment, Slow Read is only invoked if the Fast Read has uncorrectable errors (e.g., after application of ECC). In an embodiment, if the error rate of a Fast Read after ECC is less than a predetermined threshold (e.g., 1% or some other value), then only the Fast Read is performed.

In an embodiment, the Fast Read is allowed to have a much higher BER relative to a desired BER specification, whereas the Slow Read is required to meet the desired BER specification. In an embodiment, a consequence of a higher BER for Fast Read is that the read window margin increases sufficiently to allow a more aggressive sample timing for the data bits. In an embodiment, however, the Fast Read is performed so that a read disturb error rate is not increased. That is, keep the required distance from the Data Memory Cell RESET threshold voltage V_{TRD} data level to maintain a specified BER target.

In an embodiment, when a read is performed, only Fast Read Reference Memory Cell in Fast Reference Module 602_{F} is triggered along with the data bits from data modules 602₀, 602₁, 602₂, . . . , 602_{N-1}, and the Slow Read Reference Memory Cell in Slow Reference Module 602_{S} is not triggered.

In an embodiment, the data bits from data modules 602₀, 602₁, 602₂, . . . , 602_{N-1} use a Fast Read Slow Ramp rate which is much faster than the Slow Read Slow Ramp rate (e.g., the Slow Ramp depicted in FIG. 6B). In addition, in an embodiment the Fast Read uses a shorter first predetermined delay time ΔT_{D} than the one used in a Slow Read. Without wanting to be bound by any particular theory, it is believed that this enables a low latency Fast Read, albeit at a high BER.

In an embodiment, during a Slow Read both the Fast Read Reference Memory Cell in Fast Reference Module 602_{F} and the Slow Read Reference Memory Cell in Slow Reference Module 602_{S} are triggered. The Fast Read Reference Memory Cell can no longer be used to cancel the drift of any SET bits that did not trigger during the prior Fast Read. This is because triggering the Fast Read Reference Memory Cell during the Fast Read will reset the drift to zero. Because the Slow Read Reference Memory Cell was not triggered during the Fast Read, the Slow Read Reference Memory Cell continues to drift with the remaining untriggered SET bits in the line. So the Slow Read Reference Memory Cell can be used as a way to cancel out the drift component for reading these data bits.

However, to read these remaining data bits accurately, in an embodiment the Slow Read Slow Ramp rate is made slow enough to ensure that read voltage V_{RD} can be positioned correctly to achieve specified read BER. Without wanting to be bound by any particular theory, it is believed that the Slow Read will have a latency that is about twice the latency of a Fast Read. But because the Slow Read happens infrequently (e.g., less than 1% of the time), the impact of the longer Slow Read latency on the average read operation is small.

FIG. 6D1-6D2 are simplified diagrams of threshold voltage and read voltage V_{RD} distributions for a Fast Read process and a Slow Read Process, respectively, of the example threshold voltage reference read system 600b of FIG. 6C. The two diagrams illustrate the tradeoff between speed and BER.

Without wanting to be bound by any particular theory, it is believed that the threshold voltage reference read techniques described above provides highly reliable, fast read operation of OTS memory cells and may consume lower power than existing demarcation read techniques.

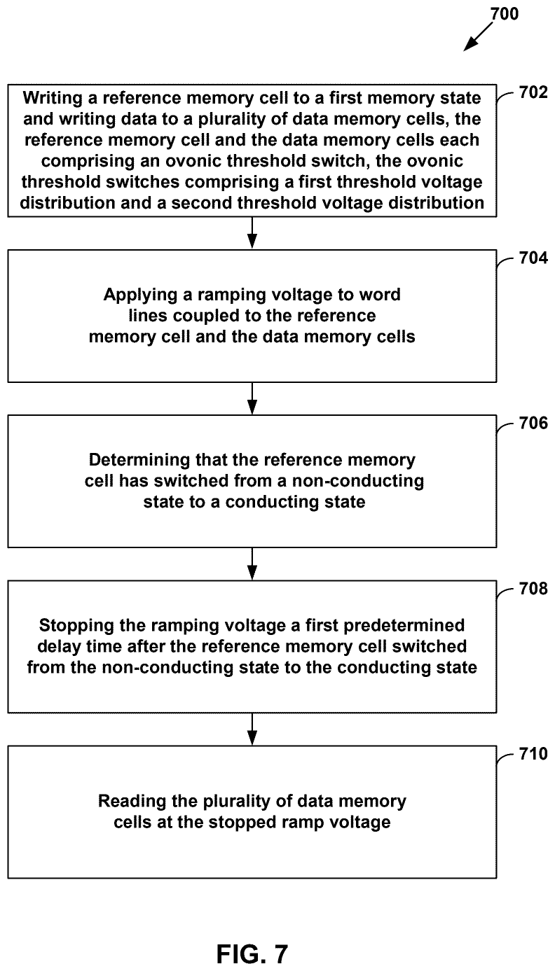

FIG. 7 depicts a flow diagram of an embodiment of a method 700 of a threshold voltage reference read technique in accordance with this technology.

At step 702, writing a reference memory cell to a first memory state and writing data to a plurality of data memory cells, the reference memory cell and the data memory cells each comprising an ovonic threshold switch, the ovonic threshold switches comprising a first threshold voltage distribution and a second threshold voltage distribution.

At step 704, applying a ramping voltage to word lines coupled to the reference memory cell and the data memory cells.

At step 706, determining that the reference memory cell has switched from a non-conducting state to a conducting state.

At step 708, stopping the ramping voltage a first predetermined delay time after the reference memory cell switched from the non-conducting state to the conducting state.

At step 710, reading the plurality of data memory cells at the stopped ramp voltage.

One embodiment of the disclosed technology includes an apparatus that includes a memory array that has a first memory cell including a first two-terminal element having a first threshold voltage and a second threshold voltage, and a second memory cell including a second two-terminal element having a third threshold voltage and a fourth threshold voltage, and a control circuit coupled to the memory array. The control circuit is configured to apply a first voltage signal to the first memory cell to cause the first two-terminal element to have the first threshold voltage, apply a second voltage signal to the second memory cell to cause the second two-terminal element to have either the third threshold voltage or the fourth threshold voltage, apply a third voltage signal to the first memory cell and the second memory cell, the third voltage signal increasing at a first ramp rate, determine that the first memory cell switches from a non-conducting state to a conducting state, and read the second memory cell using the third voltage signal at a first predetermined delay time after the first memory cell switches from the non-conducting state to the conducting state.

One embodiment of the disclosed technology includes a system that includes a plurality of data modules, each data module including a plurality of data memory cells, each data memory cell including an ovonic threshold switch, the ovonic threshold switches including a first threshold voltage distribution and a second threshold voltage distribution, a first reference module that includes a first plurality of first reference memory cells, each first reference memory cell including an ovonic threshold switch including a first reference threshold voltage distribution, a plurality of word lines coupled to the plurality of data memory cells and the first plurality of first reference memory cells, a voltage ramp control circuit coupled to the plurality of data modules and the first reference module, the voltage ramp control circuit configured to generate a ramping output voltage, and a control circuit coupled to the plurality of data modules, the first reference module and the voltage ramp control circuit. The control circuit is configured to couple the ramping output voltage to a selected data memory cell from each of the plurality of data modules and a selected first reference memory cell from the first reference module, determine that the selected first reference memory cell switches from a non-conducting state to a conducting state, and first read each of the selected data memory cells using the ramping output voltage a first predetermined delay time after the selected first reference memory cell switches from the non-conducting state to the conducting state.

One embodiment of the disclosed technology includes a method that includes writing a reference memory cell to a first memory state and writing data to a plurality of data memory cells, the reference memory cell and the data memory cells each including an ovonic threshold switch, the ovonic threshold switches including a first threshold voltage distribution and a second threshold voltage distribution, applying a ramping voltage to word lines coupled to the reference memory cell and the data memory cells, determining that the reference memory cell has switched from a non-conducting state to a conducting state, stopping the ramping voltage a first predetermined delay time after the reference memory cell switched from the non-conducting state to the conducting state, and reading the plurality of data memory cells at the stopped ramp voltage.

For purposes of this document, a first layer may be over or above a second layer if zero, one, or more intervening layers are between the first layer and the second layer.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments and do not necessarily refer to the same embodiment.

For purposes of this document, a connection may be a direct connection or an indirect connection (e.g., via another part). In some cases, when an element is referred to as being connected or coupled to another element, the element may be directly connected to the other element or indirectly connected to the other element via intervening elements. When an element is referred to as being directly connected to another element, then there are no intervening elements between the element and the other element.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An apparatus comprising:
a memory array comprising a first memory cell comprising a first two-terminal element having a first threshold voltage and a second threshold voltage, and a second memory cell comprising a second two-terminal element having a third threshold voltage and a fourth threshold voltage; and
a control circuit coupled to the memory array, the control circuit configured to:
apply a first voltage signal to the first memory cell to cause the first two-terminal element to have the first threshold voltage;
apply a second voltage signal to the second memory cell to cause the second two-terminal element to have either the third threshold voltage or the fourth threshold voltage;
apply a third voltage signal to the first memory cell and the second memory cell, the third voltage signal increasing at a first ramp rate;
determine that the first memory cell switches from a non-conducting state to a conducting state; and
read the second memory cell using the third voltage signal a first predetermined delay time after the first memory cell switches from the non-conducting state to the conducting state.

2. The apparatus of claim 1, wherein the control circuit is further configured to cause the third voltage signal to change to a second ramp rate lower than the first ramp rate when the first memory cell switches from the non-conducting state to the conducting state.

3. The apparatus of claim 1, wherein the control circuit is further configured to cause the third voltage signal to stop increasing at the first predetermined delay time after the first memory cell switches from the non-conducting state to the conducting state.

4. The apparatus of claim 1, wherein:
the first memory cell is configured to be read using a read voltage comprising a first polarity; and
the first two-terminal element has the first threshold voltage when the first memory cell was previously written using a write signal comprising the first polarity, and has the second threshold voltage when the first memory cell was previously written using a write signal comprising a second polarity opposite the first polarity.

5. The apparatus of claim 4, wherein:
the second memory cell is configured to be read using a read voltage comprising the first polarity; and
the second two-terminal element has the third threshold voltage when the second memory cell was previously written using a write signal comprising the first polarity, and has the fourth threshold voltage when the second memory cell was previously written using a write signal comprising the second polarity.

6. The apparatus of claim 1, wherein:
the first threshold voltage and the third threshold voltage comprise a first threshold voltage distribution; and
the second threshold voltage and the fourth threshold voltage comprises a second threshold voltage distribution.

7. The apparatus of claim 1, wherein:
the first threshold voltage is lower than the second threshold voltage; and
the third threshold voltage is lower than the fourth threshold voltage.

8. The apparatus of claim 1, wherein:
the first threshold voltage and the second threshold voltage drift after the first memory cell is written; and
the third threshold voltage and the fourth threshold voltage drift after the second memory cell is written.

9. The apparatus of claim 8, wherein the first threshold voltage, the second threshold, the third threshold voltage and the fourth threshold voltage drift at substantially a same rate.

10. The apparatus of claim 1, wherein the first two-terminal element and the second two-terminal element each comprise a selector material that provides a bidirectional current flow when the current or voltage exceeds a threshold value.

11. The apparatus of claim 1, wherein the first two-terminal element and the second two-terminal element each comprise a chalcogenide material.

12. The apparatus of claim 1, wherein the first two-terminal element and the second two-terminal element each comprise one or more of a GeSeAs alloy, a GeSeAsTe alloy, a GeTeAs alloy, a GeSeTe alloy, a GeSe alloy, a SeAs alloy, a AsTe alloy, a GeTe alloy, a SiTe alloy, a SiAsTe alloy, and a SiAsSe alloy.

13. The apparatus of claim 1, wherein the first two-terminal element and the second two-terminal element each comprise an ovonic threshold switch.

14. A system comprising:
a plurality of data modules, each data module comprising a plurality of data memory cells, each data memory cell comprising an ovonic threshold switch, the ovonic threshold switches comprising a first threshold voltage distribution and a second threshold voltage distribution;
a first reference module that includes a first plurality of first reference memory cells, each first reference memory cell comprising an ovonic threshold switch comprising a first reference threshold voltage distribution;
a plurality of word lines coupled to the plurality of data memory cells and the first plurality of first reference memory cells;
a voltage ramp control circuit coupled to the plurality of data modules and the first reference module, the voltage ramp control circuit configured to generate a ramping output voltage; and
a control circuit coupled to the plurality of data modules, the first reference module and the voltage ramp control circuit, the control circuit configured to:
couple the ramping output voltage to a selected data memory cell from each of the plurality of data modules and a selected first reference memory cell from the first reference module;
determine that the selected first reference memory cell switches from a non-conducting state to a conducting state; and
first read each of the selected data memory cells using the ramping output voltage a first predetermined delay time after the selected first reference memory cell switches from the non-conducting state to the conducting state.

15. The system of claim 14, further comprising:
a second reference module that includes a second plurality of second reference memory cells, each second reference memory cell comprising an ovonic threshold switch comprising a second reference threshold voltage distribution,
wherein the control circuit is further configured to:
couple the ramping output voltage to a selected second reference memory cell from the second reference module;
determine that the selected first reference memory cell switches from a non-conducting state to a conducting state; and
second read each of the selected data memory cells using the ramping output voltage a first predetermined delay time after the selected second reference memory cell switches from the non-conducting state to the conducting state.

16. The system of claim 15, wherein the second read occurs before the first read.

17. The system of claim 15, wherein the first read comprises a first error rate and the second read comprises a second error rate higher than the first error rate.

18. The system of claim 14, wherein each ovonic threshold switch comprises a chalcogenide material.

19. The system of claim 14, wherein each ovonic threshold switch comprises one or more of a GeSeAs alloy, a GeSeAsTe alloy, a GeTeAs alloy, a GeSeTe alloy, a GeSe alloy, a SeAs alloy, a AsTe alloy, a GeTe alloy, a SiTe alloy, a SiAsTe alloy, and a SiAsSe alloy.

20. A method comprising:
writing a reference memory cell to a first memory state and writing data to a plurality of data memory cells, the reference memory cell and the data memory cells each comprising an ovonic threshold switch, the ovonic threshold switches comprising a first threshold voltage distribution and a second threshold voltage distribution;
applying a ramping voltage to word lines coupled to the reference memory cell and the data memory cells;
determining that the reference memory cell has switched from a non-conducting state to a conducting state;
stopping the ramping voltage a first predetermined delay time after the reference memory cell switched from the non-conducting state to the conducting state; and
reading the plurality of data memory cells at the stopped ramp voltage.
